(19) United States
(12) Patent Application Publication
(10) Pub. No.: US 2012/0217562 A1
(43) Pub. Date: Aug. 30, 2012

(54) SEMICONDUCTOR DEVICE AND METHOD OF MANUFACTURING THE SAME

(75) Inventor: Kyoung Han LEE, Icheon-si (KR)

(73) Assignee: Hynix Semiconductor Inc., Icheon-si (KR)

(21) Appl. No.: 13/240,873

(22) Filed: Sep. 22, 2011

(30) Foreign Application Priority Data
Feb. 28, 2011 (KR) 10-2011-0017803

(51) Int. Cl. H01L 29/78

(52) U.S. Cl. 257/314; 257/E29.255

(57) ABSTRACT

A semiconductor device capable of maximizing a channel area in a pillar and a method of manufacturing the same are provided. The semiconductor device includes a pillar disposed on a semiconductor substrate and having first to fourth side surfaces, a first bit line disposed in the first side surface, a storage node junction region disposed in the third side surface facing the first side surface, and a gate disposed in the second side surface or a fourth side surface facing the second surface.

### CROSS-REFERENCES TO RELATED APPLICATION

The present application claims priority to Korean patent application number 10-2011-0017803, filed on 28 Feb. 2011, which is incorporated by reference in its entirety.

### BACKGROUND OF THE INVENTION

1. Technical Field

The present invention relates to a semiconductor device and a method of manufacturing the same, and more particularly, to a semiconductor device having a word line and a bit line and a method of manufacturing the same.

2. Related Art

In general, a semiconductor is a material characterized by electrical conductivity and is a material between a conductor and an insulator. A semiconductor is similar to an insulator in an intrinsic state, but it has a property that electrical conductivity is increased by adding an impurity or by other manipulation. A semiconductor is used for fabricating semiconductor devices, such as transistors, by adding an impurity and connecting conductors and an apparatus. The apparatus, in turn, is fabricated using the semiconductor device and has various functions; it is thus referred to as a semiconductor apparatus. A semiconductor memory device is a typical example of such a semiconductor apparatus.

Semiconductor memory devices are comprised of unit cells, each of which is constituted of a capacitor and a transistor. The transistor is used to temporarily store data and to transfer data between a bit line and the capacitor in response to a control signal (a word line) using the semiconductor property that electrical conductivity changes according to the environment. The transistor includes three regions, namely a gate, a source, and a drain, and electric charges move between the source and drain according to a control signal applied to the gate. The electric charges move between the source and drain through a channel region, which uses the semiconductor property.

When a transistor is manufactured on a semiconductor substrate by a conventional method, a gate is formed on the semiconductor substrate and an impurity is implanted in the semiconductor substrate at both sides of the gate to form a source and a drain. In this case, a portion of the substrate between the source and drain below the gate serves as a channel region of the transistor. The transistor, having a horizontal channel region, occupies the semiconductor substrate by a predetermined area. It is difficult to reduce a unit cell size of the semiconductor memory device having this complicated structure due to a plurality of transistors included therein.

As a unit cell size is reduced, the number of the semiconductor memory devices producible per wafer increases, thereby improving the throughput. Several methods for reducing a unit cell size of the semiconductor memory device have been suggested. One of these methods uses a three-dimensional transistor including a vertical transistor, which has a vertical channel region, instead of a conventional horizontal transistor, which has a horizontal channel region.

### SUMMARY

Embodiments of the present invention are directed to provide a semiconductor device having a new structure capable of maximizing a channel area in a pillar and a method of manufacturing the same.

According to one aspect of an exemplary embodiment, a semiconductor device having a new structure includes a pillar disposed on a semiconductor substrate and having first to fourth sides, a first bit line disposed in the first side of the pillar, a storage node junction region disposed in the third side of the pillar facing the first side, and a gate disposed in the second side of the pillar or a fourth side facing the second side.

The semiconductor device may further include a second bit line, which is connected to a lower edge of the first bit line and extends in a direction perpendicular to the pillar.

The first bit line may have the same material as the second bit line and the first and second bit lines may form an inverse T-shaped structure in one cell.

The first bit line may have a rectangular shape, an elliptical shape, or a triangular shape.

The semiconductor device may further include a word line, which is connected to an upper edge of the gate and extends in a direction perpendicular to the pillar.

The gate may be disposed on the second side and the fourth side of the pillar.

The gate may be further disposed on an upper surface of the pillar and have an inverse U-shaped structure.

In addition, the gate may be disposed on the whole second side or the whole fourth side of the pillar, or partially disposed on an upper portion of the second side or the fourth side of the pillar.

The semiconductor device may further include a storage node, which is connected to the storage node junction region and surrounds the pillar, the first bit line and the gate.

The semiconductor device may further include a dielectric layer surrounding a circumferential surface of the storage node, and a plate node surrounding the dielectric layer. The pillar may have a rectangular columnar shape or a circular cylindrical shape.

According to another aspect of another exemplary embodiment, a method of manufacturing a semiconductor device having a new structure includes forming a pillar having a first to fourth sides on a semiconductor substrate, forming a first bit line in the first side of the pillar, forming a storage node junction region in the third side of the pillar facing the first side, and forming a gate in the second side or the fourth side of the pillar.

The forming a first bit line may further include forming a second bit line connected to a lower edge of the first bit line and extending in a direction perpendicular to the pillar.

The forming the first bit line and the second bit line may include forming an insulating layer on the whole surface of the semiconductor substrate on which the pillar is formed, etching the insulating layer to expose the first side of the pillar, forming a conduction layer in a portion in which the insulating layer is etched, etching a portion of the conduction layer, forming an insulating layer in a portion in which the conduction layer is etched, and etching portions of the conduction layer and the insulating layer to form a vertical pillar insulating layer surrounding the second side and the fourth side of the pillar.

The pillar insulating layer may be further formed on an outer surface of the first bit line.

The method may further include forming a storage node connected to the storage node junction region and surrounding the pillar, the first bit line and the gate after the forming the first bit line.

The method may further include etching the insulating layer of a periphery of the storage node to form a dielectric layer on a surface of the storage node, and forming a plate node surrounding the dielectric layer.

The forming a gate may further include a word line connected to an upper edge of the gate and extending in a direction perpendicular to the pillar.

The forming the gate and the word line may include forming an insulating layer on the whole surface of the semiconductor substrate on which the pillar is formed, etching the insulating layer to expose the second side, the fourth side and an upper surface of the pillar, and forming a conduction layer in a portion in which the insulating layer is etched.

The method may further include forming a vertical pillar insulating layer surrounding the first to fourth sides of the pillar before the etching the insulating layer. The etching the insulating layer may include exposing the vertical pillar insulating layer.

In an embodiment, a method of manufacturing a semiconductor device includes forming a pillar having first to fourth sides over a semiconductor substrate, the pillar extending along a first direction; forming a first bit line over the first side of the pillar; forming a storage node junction region over the third side of the pillar opposite to the first side; and forming a gate over the second side or the fourth side of the pillar.

The forming the first bit line further includes forming a second bit line coupled to a lower edge of the first bit line and extending in a direction perpendicular to the pillar.

The steps of forming the first bit line and forming the second bit line include: forming an insulating layer over the semiconductor substrate over which the pillar is formed; etching the insulating layer to expose the first side of the pillar; forming a conduction layer in a portion in which the insulating layer is etched; etching a portion of the conduction layer; forming an insulating layer in a portion in which the conduction layer is etched; and etching portions of the conduction layer and the insulating layer to form a vertical pillar insulating layer surrounding the second side and the fourth side of the pillar.

The vertical pillar insulating layer is further formed over an outer surface of the first bit line.

The method further includes forming a storage node coupled to the storage node junction region and surrounding the pillar, the first bit line and the gate. The insulating layer of a periphery of the storage node is etched to form a dielectric layer over a surface of the storage node; and a plate node surrounding the dielectric layer is formed.

The step of forming the gate further includes coupling a word line to an upper edge of the gate, wherein the word line extends in a direction perpendicular to the pillar. The step of forming the gate and the word line includes: forming an insulating layer over the whole surface of the semiconductor substrate over which the pillar is formed; etching the insulating layer to expose the second side, the fourth side, and an upper surface of the pillar; and forming a conduction layer in a portion in which the insulating layer is etched.

The method further includes forming a vertical pillar insulating layer surrounding the first to fourth sides of the pillar, wherein the step of etching the insulating layer includes exposing the vertical pillar insulating layer.

These and other features, aspects, and embodiments are described below in the section entitled “DESCRIPTION OF EXEMPLARY EMBODIMENT.”

### BRIEF DESCRIPTION OF THE DRAWINGS

The above and other aspects, features, and other advantages of the subject matter of the present disclosure will be more clearly understood from the following detailed description taken in conjunction with the accompanying drawings, in which:

FIG. 1 a plan view schematically illustrating a semiconductor device according to an exemplary embodiment of the present invention;

FIG. 2 is a perspective view of a semiconductor device according to an exemplary embodiment;

FIG. 3A is a cross-sectional view of the semiconductor device of FIG. 2 taken along A-A′ line;

FIG. 3B is a cross-sectional view of the semiconductor device of FIG. 2 taken along a line perpendicular to A-A′;

FIG. 4 is a plan view illustrating one cell of a semiconductor device according to an exemplary embodiment of the present invention;

FIGS. 5A and 5B are cross-sectional views of the semiconductor device taken along lines B-B′ and C-C′ of FIG. 4;

FIGS. 6A to 6P are perspective views and cross-sectional views illustrating a method of manufacturing a semiconductor device according to an exemplary embodiment of the present invention;

FIGS. 7A to 7I are cross-sectional views illustrating portions of a method of manufacturing a semiconductor device according to an exemplary embodiment of present invention; and

FIGS. 8 to 14 are diagrams illustrating a semiconductor device according to another exemplary embodiment of the present invention.

### DESCRIPTION OF EXEMPLARY EMBODIMENT

Exemplary embodiments are described herein with reference to drawings that are schematic illustrations of exemplary embodiments (and intermediate structures). As such, variations from the shapes of the illustrations that result, for example, from manufacturing techniques and/or tolerances, are to be expected. Thus, exemplary embodiments should not be construed as limited to the particular shapes of regions illustrated herein, but may also include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present. Moreover, directional words such as “above,” “below,” “upper,” “lower,” “right,” and “left,” among others, used in reference to the drawings are merely for illustrative convenience and should not be construed as limiting.

Hereinafter, a semiconductor device and a method of manufacturing the same according to an exemplary embodiment of the present invention will be described in further detail with reference to the accompanying drawings.

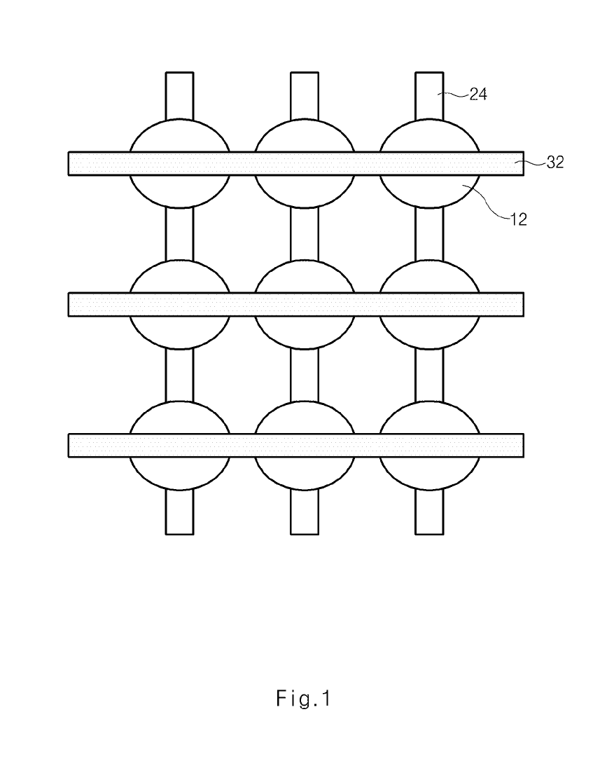

FIG. 1 is a plan view schematically illustrating a semiconductor device according to an exemplary embodiment of the present invention. Referring to FIG. 1, a plurality of pillars 12 are regularly arranged on a semiconductor substrate (not shown) and each of word lines 32 and each of bit lines 24 cross each other and are connected to each of pillars 12 to constitute one cell. The word line 32 and the bit line 24 may be formed so that the word line 32 vertically crosses the bit line 24 when viewed in a plan view. This structure, when viewed in a plan view, is the same as the conventional vertical gate.

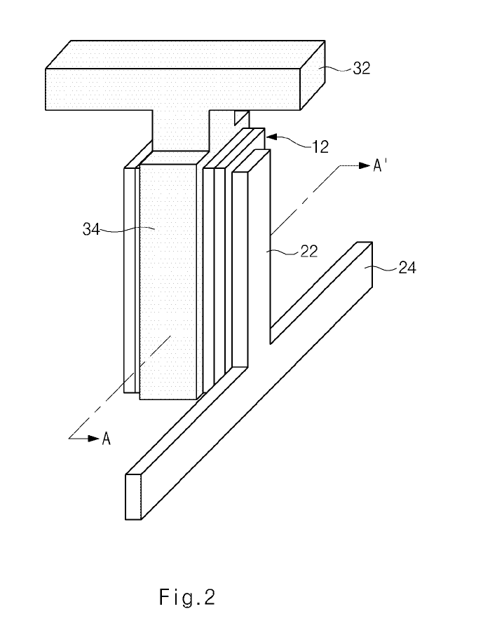

FIG. 2 is a perspective view of a semiconductor device according to an exemplary embodiment of the present invention, which illustrates a pillar 12 and a word line 32, a gate 34, and first and second bit lines 22 and 24 formed around the pillar 12. Referring to FIG. 2, the word line 32 is formed on the pillar 12 to have a line type extending along a direction crossing over the pillar 12. The second bit line 24 is formed below the pillar 12 to have a line type extending in a direction (a direction taken along line A-A′ of FIG. 2) perpendicular to the word line 32.

The gate 34 is formed below the word line 32 so that the gate 34 extends downward to be connected to a side of the pillar 12. The gate 34 may be formed of the same material as the word line 32. The gate 34 may be formed to be coupled with two sides of the pillar 12 or with only one side of the pillar 12.

The first bit line 22 is formed in a region in which the second bit line 24 and the pillar 12 are coupled with each other so that the first bit line 22 extends upward with respect to the second bit line 24 to be connected with a side of the pillar 12. The first bit line 22 may be formed of the same material as the second bit line 24. The first bit line 22 and the second bit line 24 may form an inverse T-shaped structure in one cell.

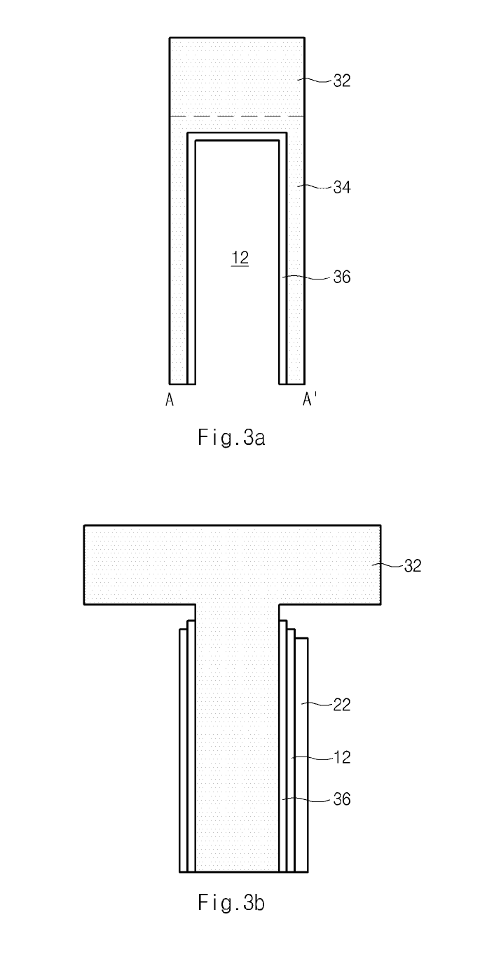

FIG. 3A is a cross-sectional view of the semiconductor device of FIG. 2 taken along the A-A′ line and FIG. 3B is a cross-sectional view of the semiconductor device of FIG. 2 taken along a line perpendicular to A-A′. Referring to FIG. 3A, a gate insulating layer 36 is formed on a surface of the pillar 12 to have a predetermined thickness. The gate insulating layer 36 may include an oxide layer. The gate insulating layer 36 may be formed by an oxidation process applied to the pillar 12 or by depositing an oxide layer on the surface of the pillar 12 through a deposition process. The gate 34 is formed to be coupled with left and right sides and an upper surface of the pillar 12 on which the gate insulating layer 36 is formed. The word line 32 is formed over the gate 34 so that the word line 32 is coupled to the gate 34. Thus, in the semiconductor device according to an exemplary embodiment, left and right side surface areas and an upper surface area of the pillar 12 are used as a channel of a transistor so that the area of the channel can be maximized to improve performance of the transistor.

Referring to FIG. 3B, the gate insulating layer 36 is also formed on the surface of the pillar 12 to have a predetermined thickness and the first bit line 22 is formed on one side of the pillar, where the gate insulating layer 36 is formed, so that the first bit line 22 is coupled with the one side of the pillar 12.

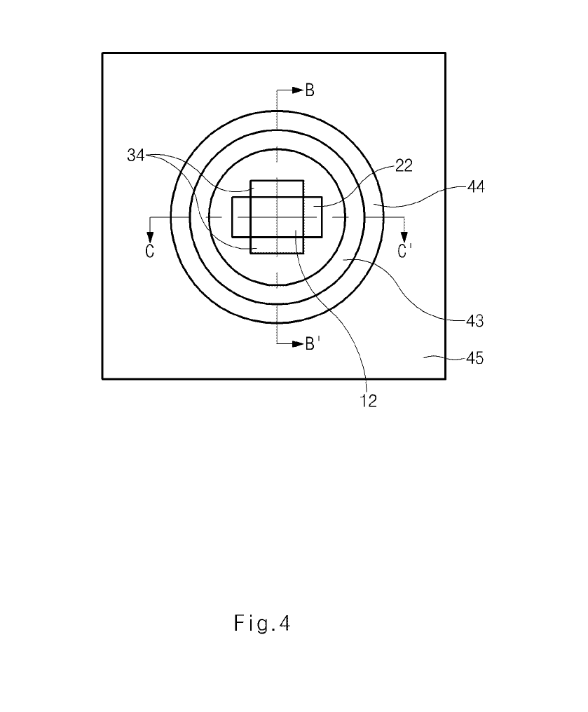

FIG. 4 is a plan view illustrating one cell of a semiconductor device according to an exemplary embodiment of the present invention, which illustrates a gate 34 and a first bit line 22 along with a capacitor, comprising a storage node 43, a dielectric layer 44, and a plate node 45 as compared with FIG. 1. Referring to FIG. 4, the gate 34 is formed at upper and lower sides of the pillar 12 and the first bit line 22 is formed at a right side of the pillar 12. The storage node 43, the dielectric layer 44, and the plate node 45 are sequentially formed to surround the periphery of the pillar 12 on which the gate 34 and the first bit line 22 are formed to constitute a capacitor.

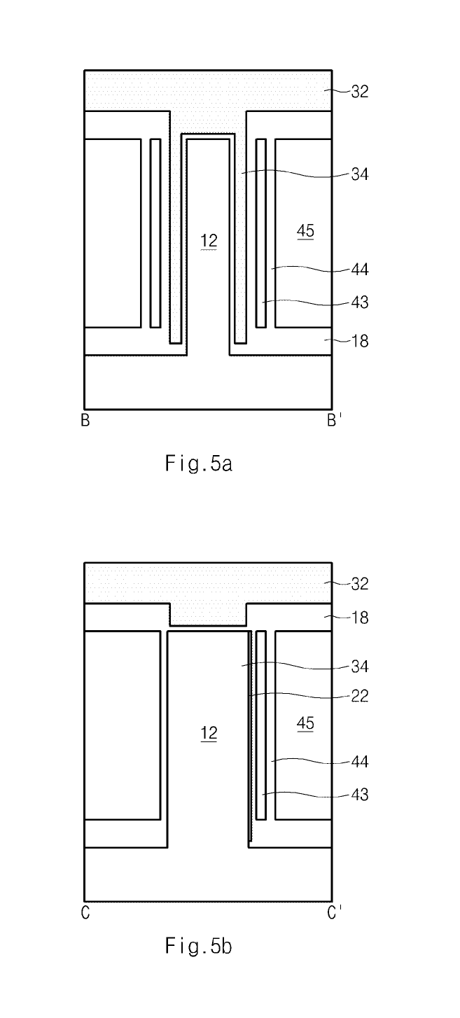

FIGS. 5A and 5B are cross-sectional views of the semiconductor device of FIG. 4 taken along lines B-B′ and C-C′. As FIG. 5A illustrates, the insulating layer 18, the storage node 43, the dielectric layer 44, and the plate node 45 are sequentially disposed in a structure of the pillar 12, the gate 34, and the word line 32. As FIG. 5B illustrates, the insulating layer 18, the storage node 43, the dielectric layer 44, and the plate node 45 are sequentially disposed around the pillar 12 and the first bit line 22.

In the semiconductor device having the above structure according to an exemplary embodiment of the present invention, the first bit line 22, which is coupled to the whole of one side of the pillar 12, and the gate 34, which surrounds two sides and an upper surface of the pillar 12, are disposed to provide a device structure capable of maximizing a channel area. Left and right areas and an upper surface area of the pillar 12, as shown in FIG. 5A, are a width of a channel. Left and right widths of the pillar 12, as shown in FIG. 5B, are a length of the channel. That is, in the semiconductor device according to an exemplary embodiment, a structure in which a transistor having a horizontal channel disposed along left and right directions of the pillar 12, and the capacitor 43, 44, and 45 disposed to surround the transistor is provided.

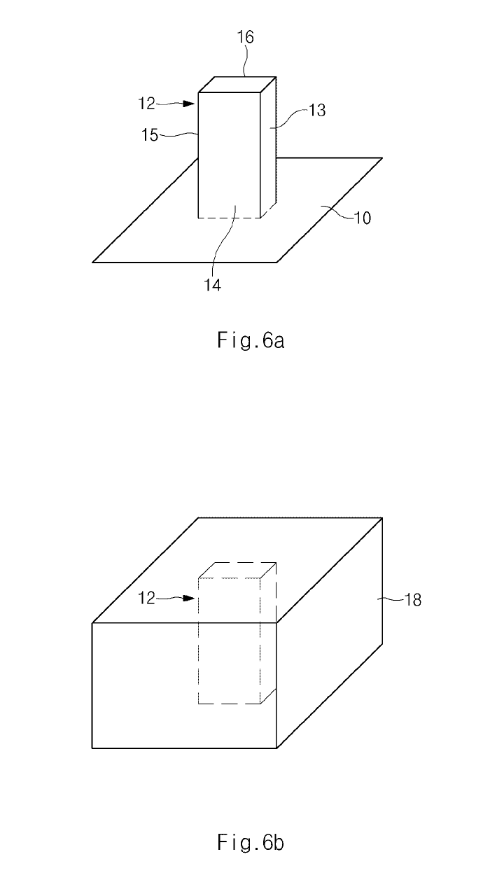

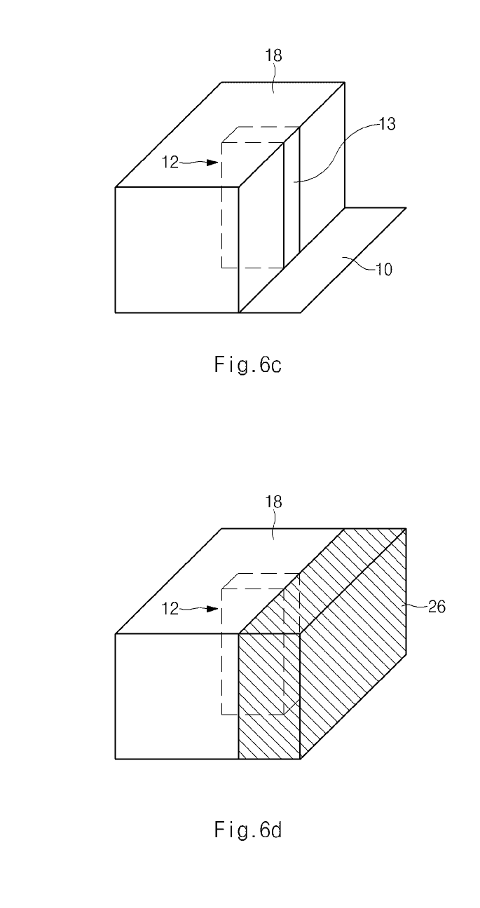

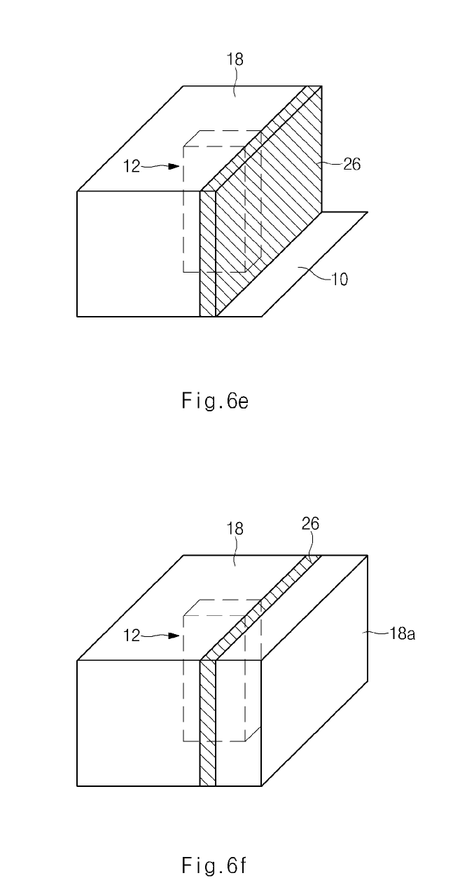

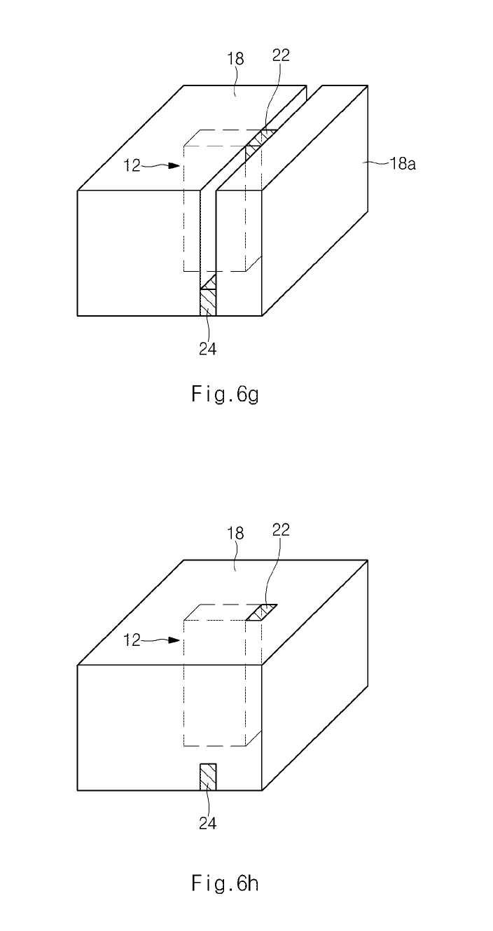

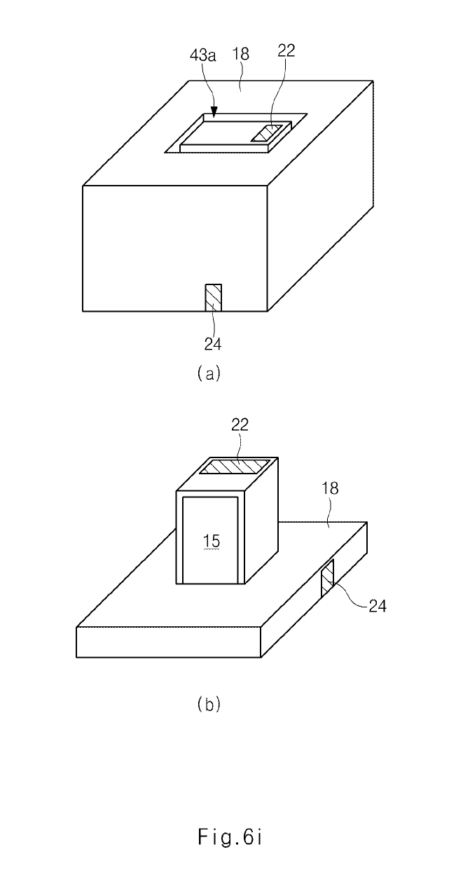

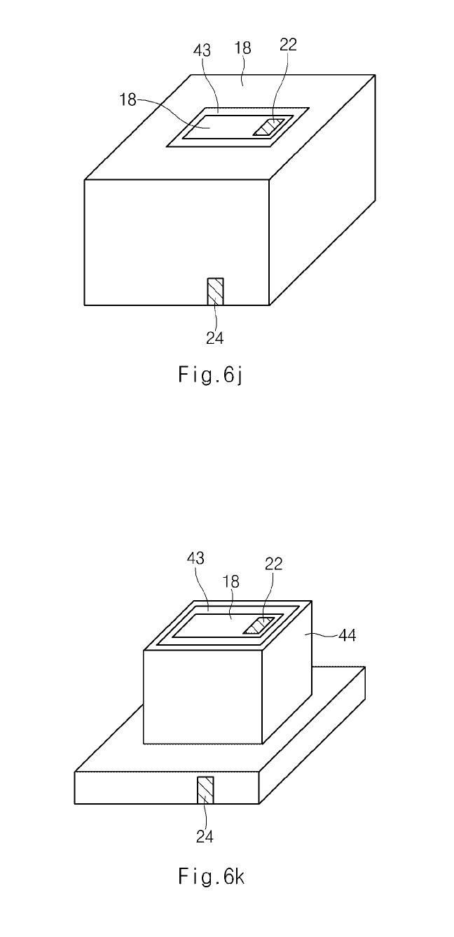

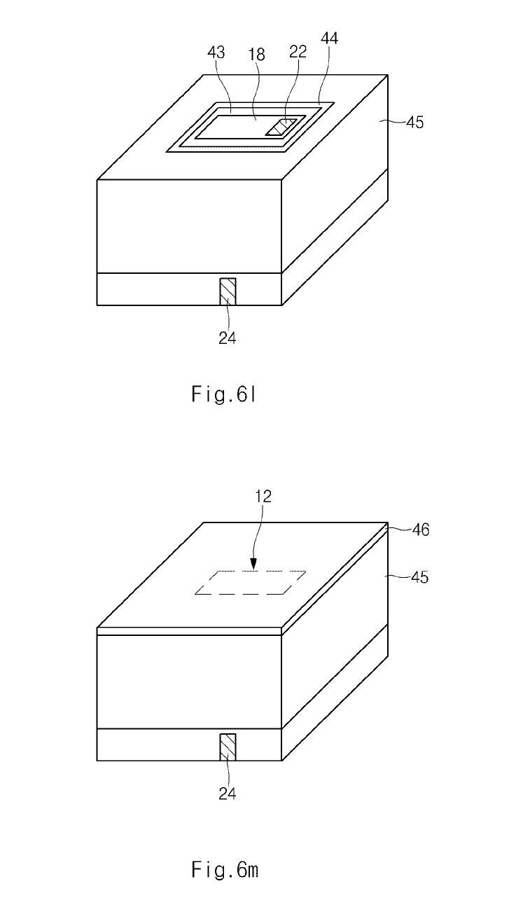

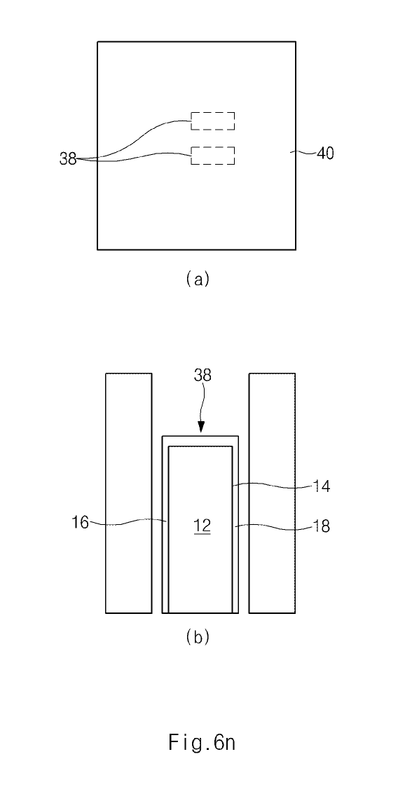

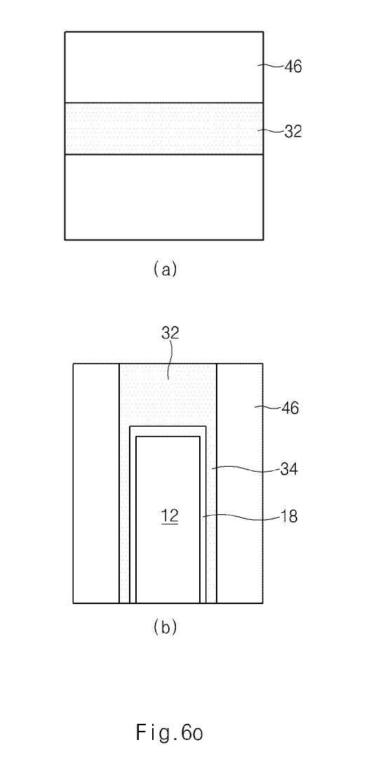

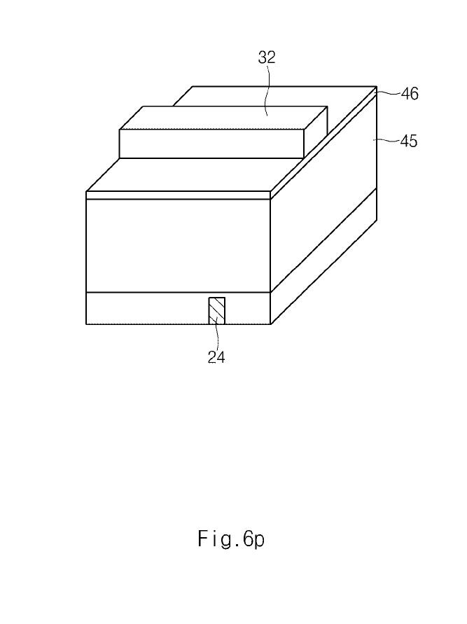

FIGS. 6A to 6P are perspective views and cross-sectional views illustrating a method of manufacturing a semiconductor device according to an exemplary embodiment of the present invention. A method of manufacturing a semiconductor device according to an exemplary embodiment will be described with reference to FIGS. 6A to 6P.

First, referring to FIG. 6A, a pillar 12 is formed on a semiconductor substrate 10 and extends in a direction perpendicular to the semiconductor substrate 10. The pillar 12 may have a square columnar shape. However, the pillar 12 may also have a circular cylinder shape or a polygonal columnar shape.

The forming the pillar 12 may include etching the substrate 10 using a mask having a pillar shape positioned on the silicon-based substrate 10 or growing the pillar 12 through a selective epitaxial growth (SEG) process using a mask having a pillar shape positioned on the silicon-based substrate 10. Hereinafter, a side of the pillar 12 is divided into four sides, which are referred to as a first side 13, a second side 14, a third side 15, and a fourth side 16, respectively. If the pillar 12 has a square columnar shape, the first to fourth sides 13 to 16 are clearly classified. However, if the pillar 12 has a circular cylinder shape or a polygonal columnar shape, a side of the pillar 12 is classified into the first to fourth sides 13 to 16 in proportion to a side surface.

Referring to FIG. 6B, an insulating layer 18 covering the pillar 12 is formed over the semiconductor substrate 10. The insulating layer 18 may include an oxide layer. Specifically, the oxide layer may include silicon oxide (SiO₂), boron phosphorus silicate glass (BPSG), phosphorus silicate glass (PSG), tetra ethyle ortho silicate (TEOS), undoped silicate glass (USG), spin on glass (SOG), high density plasma (HDP), spin on dielectric (SOD), plasma enhanced tetra ethyle ortho silicate (PE-TEOS), or silicon rich oxide (SROx).

Referring to FIG. 6C, a mask having a predetermined shape is formed over the insulating layer 18 and the insulating layer 18 is partially etched to expose the first side 13 of the pillar 12.

Referring to FIG. 6D, a conduction layer 26 is formed in a region where the insulating layer 18 is etched. Specifically, a conductive material, which includes a metal such as tungsten (W) or titanium (Ti), or a polysilicon is deposited in the region and etched by a chemical mechanical polishing (CMP) process using an upper surface of the insulating layer as an etch stop, thereby forming the conduction layer 26.

Referring to FIG. 6E, an etching process for the conduction layer 26 is performed so that the conduction layer 26 has a thinner thickness. The etching process may include forming a mask pattern on the conduction layer 26 and the insulating layer 18 and etching the conduction layer 26. Alternatively, the etching process may include etching the conduction layer using an etchback process so that the conduction layer 26 remains on a sidewall of the insulating layer 18.

Referring to FIG. 6F, an insulating layer 18a is formed in a space where the conduction layer 26 is etched to planarize an entire upper surface of the semiconductor substrate 10. The insulating layer 18a may be formed of the same material as the insulating layer 18.

Referring to FIG. 6G, a mask (not shown) is formed to cover only a portion of the conductive layer 26, which is adjacent to the pillar 12, and the exposed portion of the conduction layer 26 is etched to form an inverse T-shaped structure. A lower pattern of the etched conduction layer 26, which extends in a horizontal direction along the surface of the semiconductor substrate 10, is referred to as a second bit line 24. An extension pattern of the etched conduction layer 26, which extends upward from the second bit line 24, is referred to as a first bit line 22.

Referring to FIG. 6H, an insulating layer 18 is deposited again in a space formed by etching the conduction layer 26 to form the first and second bit lines 22 and 24, so that the entire surface of the semiconductor substrate 10 is planarized.

Referring to FIG. 6I(a), a portion of the insulating layer 18 around the pillar 12 including the first bit line 22, is etched in a rectangular shape or a circular shape (if the pillar is a circular cylinder shape) to form a recess 43a. The recess 43a is in a region in which a storage node 43 (see FIG. 6J) is to be formed. A depth of the recess 43a may be equal or similar to the height of the pillar 12. The insulating layer 18 may remain between the recess 43a and the pillar 12 at a predetermined thickness. However, as FIG. 6I(b) illustrates, the insulating layer 18 may also be etched such that the third side 15 of the pillar 12 is exposed. Referring to FIG. 6I(b), the recess 43a may expose the third side 15 of the pillar 12.

Referring to FIG. 6J, the storage node 43 is formed by filling a conductive material within the recess 43a. The process of forming the storage node 43 may include depositing a conductive material over the whole surface of the insulating layer 18, including the recess 43a, and performing a planarization process using a CMP or etch back process to separate the conductive material so that the conductive material remains only in the recess 43a.

Referring to FIG. 6K, a portion of the insulating layer 18 around the storage node 43 and the pillar 12 is etched to form a dielectric layer 44 having a predetermined thickness. Subsequently, referring to FIG. 6L, a conductive material is buried in a region in which the insulating layer 18 is etched to form a plate node 45. The process of forming the plate node 45 may use a CMP or etch back process as the process of forming the storage node 43 (see FIG. 6J).

Referring to FIG. 6M, an upper insulating layer 46, including an insulating layer such as an oxide layer, is formed to have a predetermined thickness over the insulating layer 18 in which the plate node 45 is formed. The upper insulating layer 46 serves to insulate the first bit line 22 and the storage node 43, which are conductive materials, from each other, as well as the first bit line 22 and the plate node 43, which are also conductive materials, from each other.

FIG. 6N(a) is a plan view of the semiconductor device after the process of FIG. 6M. FIG. 6N(b) is a cross-sectional view taken along a line passing a central portion of the pillar 12 after the process of FIG. 6M. Referring to FIGS. 6N(a) and (b), an upper portion of the pillar 12, on which the upper insulating layer 46 is formed, is etched using a mask having a predetermined shape to form recesses 38, thereby exposing the second side 14 and the fourth side 16. At this time, the upper insulating layer 46 may be etched so that the second and fourth sides 14 and 16 of the pillar 12 are not directly exposed, but the insulating layer 18 may remain over the surface of the pillar at a predetermined thickness. The insulating layer 18 on the surface of the pillar 12 may serve as a gate insulating layer. Alternatively, the second and fourth sides 14 and 16 of the pillar 12 may be directly exposed and an oxidation process for the surface of the silicon-based pillar 12 may be performed to form a gate oxide layer on the surface of the pillar.

FIG. 6O(a) is a plan view of the semiconductor device after the process of FIG. 6N. FIG. 6O(b) is a cross-sectional view of the semiconductor device taken along a line passing a central portion of the pillar 12 after the process of FIG. 6N. Referring to FIGS. 6O(a) and (b), the recesses 38 formed in FIG. 6N are filled with a conductive material to form a word line 32 and a gate 34. The word line 32 and the gate 34 may be formed of the same material by one deposition process and the conductive material may include a metal such as W, Ti, titanium nitride (TiN), copper (Cu), or polysilicon.

Referring to FIG. 6P, a process of removing the upper insulating layer 46 around the word line 32 may be performed.

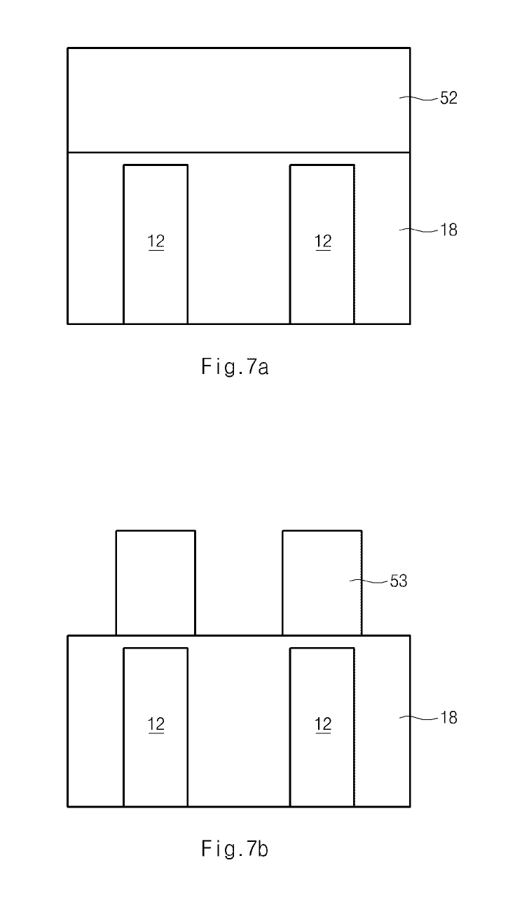

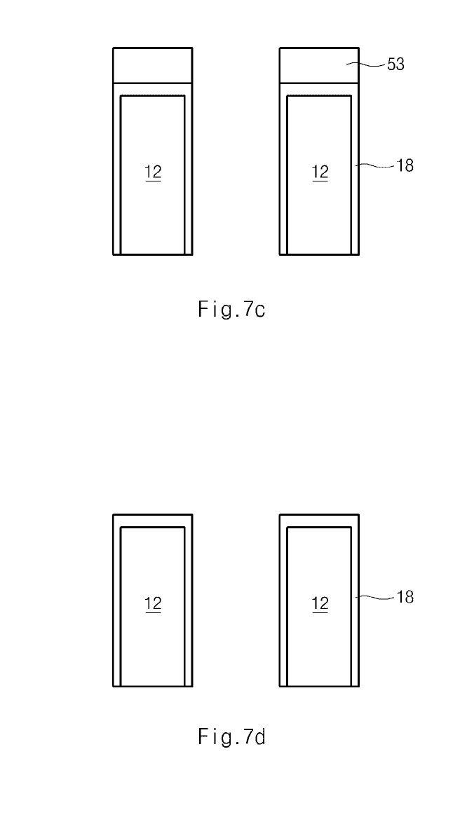

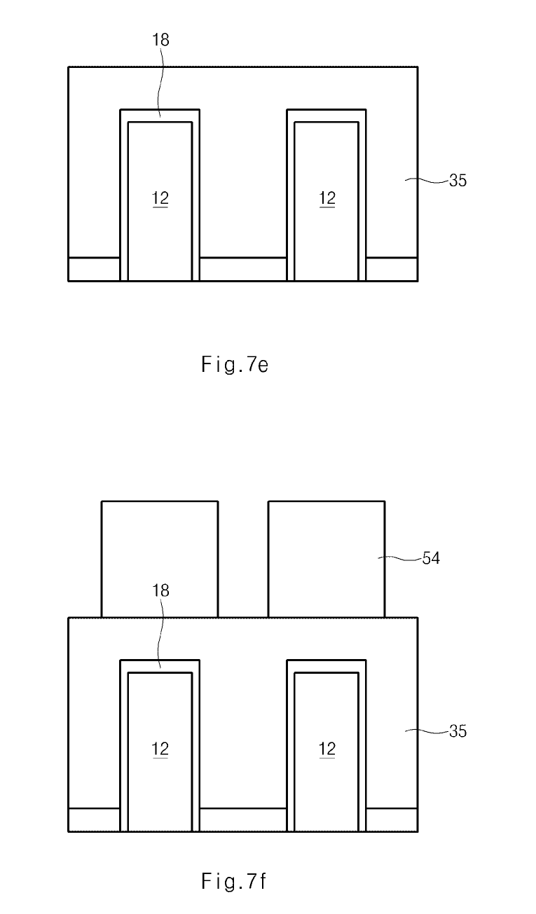

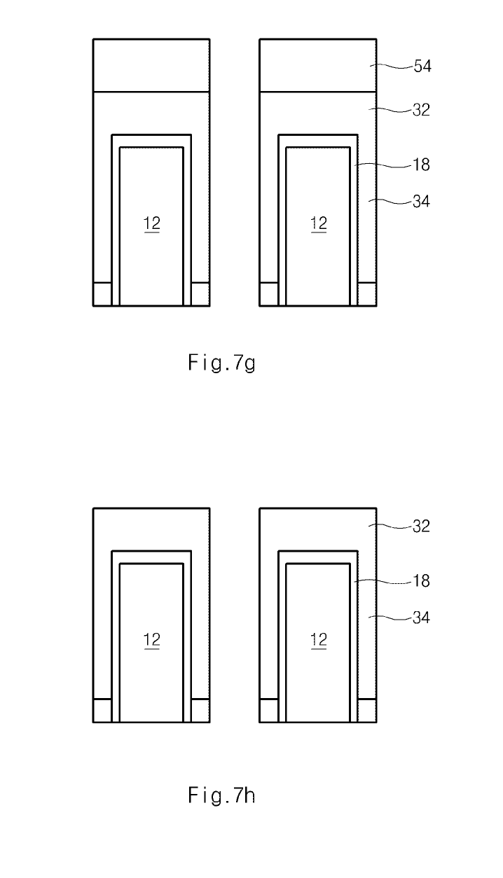

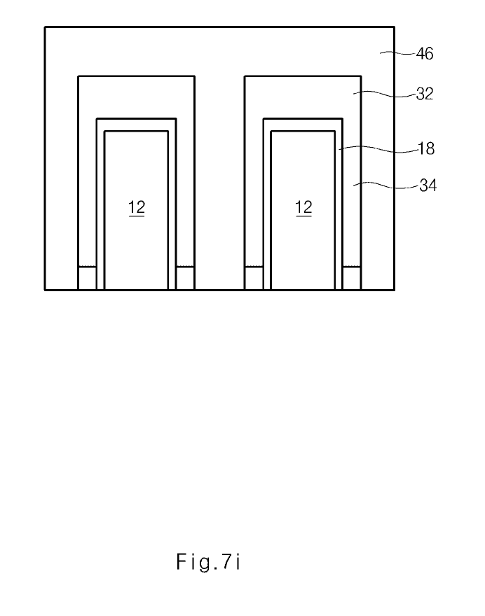

FIGS. 7A to 7I are cross-sectional views specifically illustrating is a portion of processes of manufacturing a semiconductor device and illustrating processes corresponding to the processes of FIGS. 6N and 6O in detail according to another exemplary embodiment. The process of forming a word line 32 and a gate 34 in a formation method of a semiconductor device according to another exemplary embodiment will be described with reference to FIGS. 7A to 7I in further detail.

First, referring to FIG. 7A, a first mask layer 52 is formed on an insulating layer 18, which is formed around a pillar 12. Referring to FIG. 7B, an etching process or an exposure and develop process for the first mask layer 52 is performed to form a first mask pattern 53. At this time, the line width of the first mask pattern 53 may be slightly wider than that of the pillar 12.

Referring to FIG. 7C, the insulating layer 18 is etched using the first mask pattern 53 as a mask so that the insulating layer 18 remains at a thinner thickness on a surface of the pillar 12. Referring to FIG. 7D, the first mask pattern 53 is removed. The process of FIGS. 7A to 7D corresponds to the process of FIGS. 6N(a) and (b), but there is a difference in that in the process of FIG. 6N the insulating layer 18 may be entirely etched and removed to expose a surface of the pillar 12.

Referring to FIG. 7E, a gate conductive layer 35 (hereinafter, the gate conductive layer 35 becomes a gate and word line) is formed around the pillar 12, where the thinner insulating layer 18 is formed. Referring to FIG. 7F, a second mask pattern 54 having a predetermined thickness is formed over the gate conductive layer 35. Referring to FIG. 7G, the gate conductive layer 35 is etched using the second mask pattern 54 as a mask to form the gate 34 and the word line 32.

Referring to FIG. 7H, the second mask pattern 54 is removed and referring to FIG. 7I, an upper insulating layer 46 is deposited over the entire surface of the pillar 12, including the gate 34 and the word line 32, to planarize the entire surface of the semiconductor substrate.

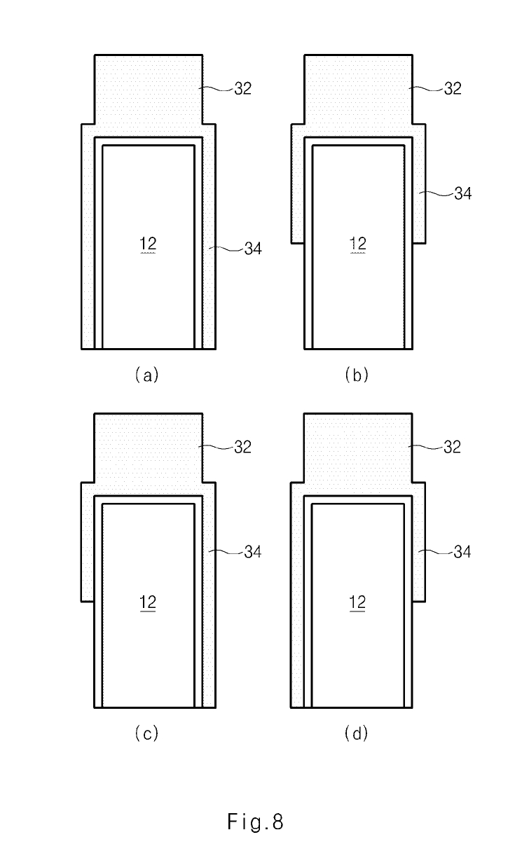

FIGS. 8 to 13 are diagrams illustrating semiconductor devices according to other exemplary embodiments of the present invention and the semiconductor devices according to other exemplary embodiments will be described with reference to FIGS. 8 to 13.

First, FIG. 8(a) of FIGS. 8(a) to (d) corresponds to the exemplary embodiment of FIG. 2. The gate 34, in the exemplary embodiment, may be formed so that the gate 34 corresponds to the entire surface of left and right sides of the pillar 12, in order to ensure a channel area, as shown in FIG. 8(a). However, when it is not easily possible to etch the periphery of the pillar 12 to have a thin line width, the gate 34 may be formed so that both gates 34 extend from the upper surface of the pillar 12 to approximately the center or only one of both gates 34 extends below the pillar 12.

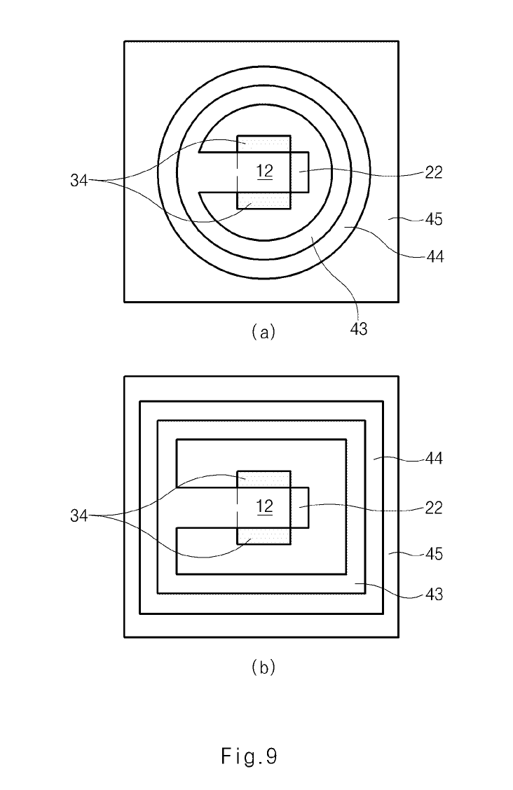

FIG. 9(a) of FIGS. 9(a) to (b) corresponds to the exemplary embodiment of FIG. 4. The shape of a storage node 43 and a dielectric layer 44 formed around the periphery of the pillar 12, when viewed in a plan view, may be a circular shape, as shown in FIG. 9(a), or a rectangular shape, as shown in FIG. 9(b).

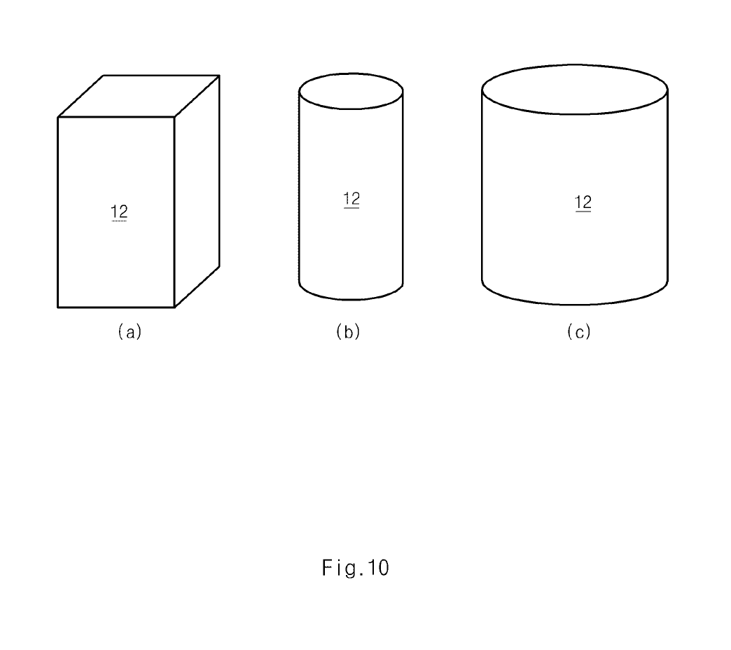

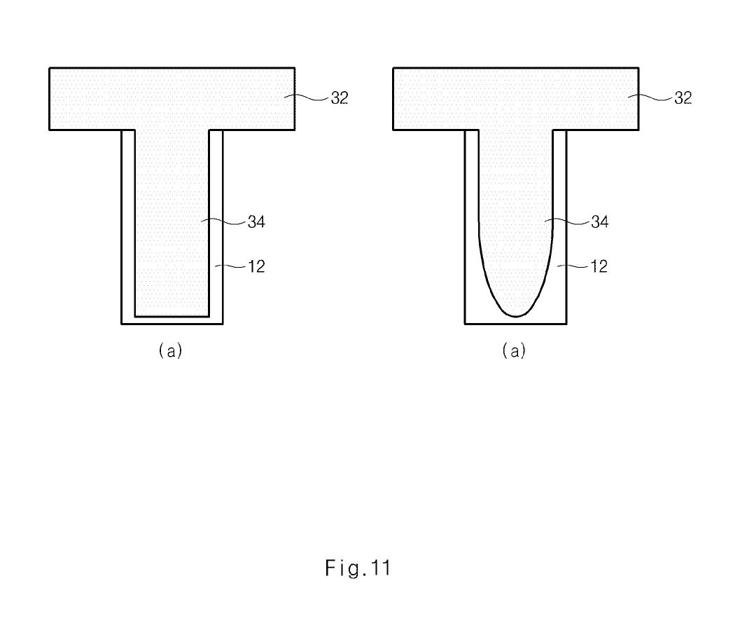

FIGS. 10(a) to (c) illustrate shapes of the pillar 12. The pillar 12 may have a square columnar shape as shown in FIG. 10(a), a circular cylinder shape as shown in FIG. 10(b), or an elliptical columnar shape as shown in FIG. 10(c).

FIGS. 11(a) and (b) are diagrams illustrating a side shape of the gate 34 disposed at a side of the pillar 12. The side shape of the gate 34 may be a substantially rectangular shape as shown in FIG. 11(a) or a circular or curved shape as shown in FIG. 11(b).

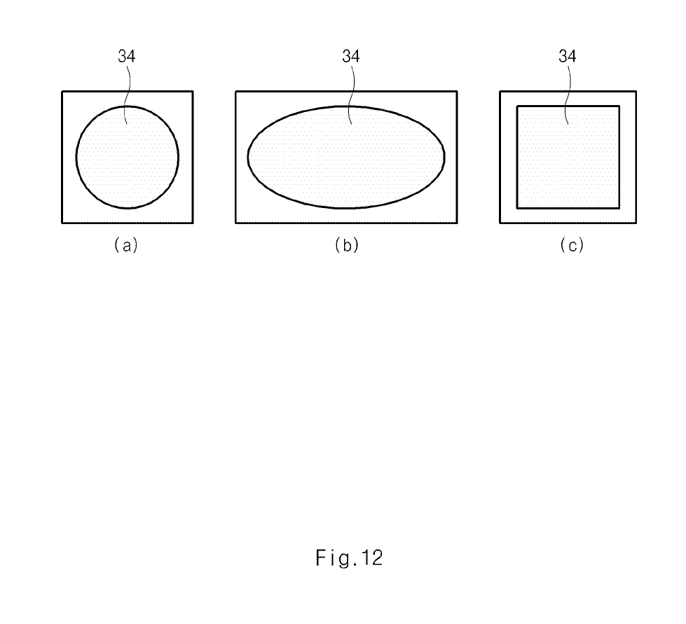

FIGS. 12(a) to (c) are cross-sectional views illustrating a portion of a gate 34, which is disposed on an upper surface of the pillar 12. The gate 34, which is disposed on a pillar 12, may be a circular shape as shown in FIG. 12(a), an elliptical shape as shown in FIG. 12(b), or a rectangular shape as shown in FIG. 12(c), according to whether the shape of the pillar 12 is a circular shape, an elliptical shape or a rectangular shape.

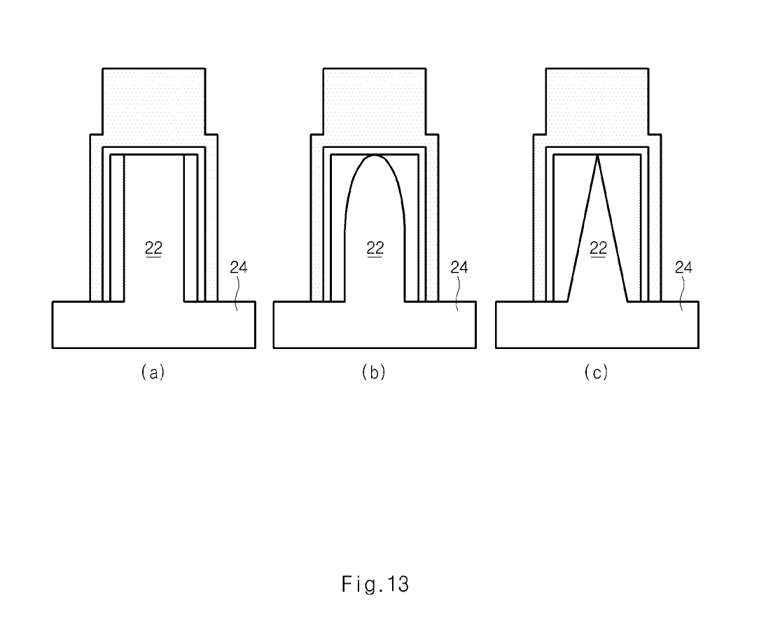

FIGS. 13(a) to (c) are diagrams illustrating a shape of a first bit line 22. The first bit line 22 may be a substantially rectangular shape as shown in FIG. 13(a), a circular or curved shape as shown in FIG. 13(b), or a triangular shape as shown in FIG. 13(c).

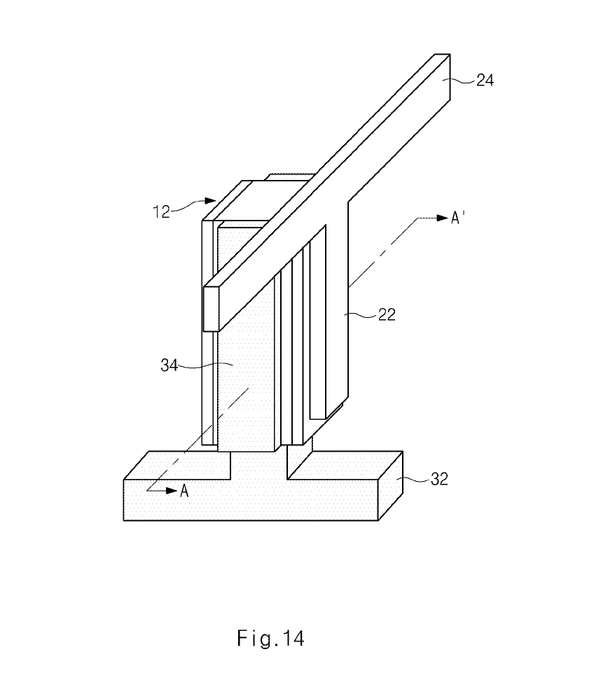

FIG. 14 is a diagram illustrating a semiconductor device according to another exemplary embodiment, which corresponds to the perspective view of FIG. 2. The structure in which the word line 32 is disposed over the pillar 12 and a second bit line 24 is disposed below the pillar 12 is illustrated in the exemplary embodiment of FIG. 2. However, the word line 32 may be disposed below the pillar 12 and the second bit line 24 may be disposed over the pillar 12, as illustrated in FIG. 14. The gate 34 or the first bit line 22 may have the same structure as in the exemplary embodiment of FIG. 2.

According to a semiconductor device having the above-described structure and a method of manufacturing the same according to the exemplary embodiments, a semiconductor device, having a new structure in which a channel area in a pillar can be maximized, is provided.

The above embodiments of the present invention are illustrative and not limitative. Various alternatives and equivalents are possible. The present invention is not limited by the embodiments described herein. Nor is the present invention limited to any specific type of semiconductor device. Other additions, subtractions, or modifications are obvious in view of the present disclosure and are intended to fall within the scope of the appended claims.

What is claimed is:

1. A semiconductor device, comprising:
a pillar disposed over a semiconductor substrate and having first to fourth sides;
a first bit line disposed over the first side of the pillar;
a storage node junction region disposed over the third side of the pillar opposite to the first side; and
a gate disposed over the second side of the pillar or the fourth side opposite to the second side.

2. The semiconductor device of claim 1, further including a second bit line which is coupled to a lower edge of the first bit line and extends in a direction perpendicular to the pillar.

3. The semiconductor device of claim 2, wherein the first bit line has the same material as the second bit line, and the first and second bit lines form an inverse T-shaped structure.

4. The semiconductor device of claim 1, wherein the first bit line has a rectangular shape, an elliptical shape, or a triangular shape.

5. The semiconductor device of claim 1, the device further comprising a word line, which is coupled to an upper edge of the gate and extends in a direction perpendicular to the pillar.

6. The semiconductor device of claim 5, wherein the gate is disposed over the second side and the fourth side of the pillar.

7. The semiconductor device of claim 6, wherein the gate is further disposed over an upper surface of the pillar and has an inverse U-shaped structure.

8. The semiconductor device of claim 6, wherein the gate is disposed over the whole second side or the whole fourth side of the pillar, or partially disposed over an upper portion of any of the second side and the fourth side of the pillar.

9. The semiconductor device of claim 1, the device further comprising a storage node, which is coupled to the storage node junction region and surrounds the pillar, the first bit line, and the gate.

10. The semiconductor device of claim 9, further comprising:
a dielectric layer surrounding a circumferential surface of the storage node; and
a plate node surrounding the dielectric layer.

11. The semiconductor device of claim 1, wherein the pillar has a rectangular columnar shape or a circular cylindrical shape.

12. A semiconductor device comprising:
is a pillar extending from a substrate;
a gate pattern formed over a first sidewall of the pillar;
a first bit line formed over a second sidewall of the pillar; and
a first storage node pattern formed over a third sidewall of the pillar;
wherein the first and the second sidewalls are coupled to each other through the first sidewall.

13. The semiconductor device of claim 12, the device further comprising:
a second storage node pattern extending from the first storage node pattern and surrounding the pillar;

14. The semiconductor device of claim 13, the device further comprising:
an insulating layer formed between the pillar and the second storage node pattern in such a manner as to insulate the gate pattern and the first bit line from the storage node pattern.

15. The semiconductor device of claim 12, wherein the gate pattern extends over a top surface of the pillar, and
wherein the first and the second sidewalls are coupled to each other through the top surface of the pillar.

16. The semiconductor device of claim 15, wherein the gate pattern further extends over a fourth sidewall of the pillar, and
wherein the first and the second sidewalls are coupled to each other through the fourth sidewall.

17. The semiconductor device of claim 16, wherein the gate pattern is in an inverse U shape.

18. The semiconductor device of claim 12, wherein the pillar is a cylinder pattern or a polygonal pattern.

19. The semiconductor device of claim 13, wherein the second storage node pattern is configured to have a cylinder outer contour or a polygonal outer contour.

20. The semiconductor device of claim 12, the device further comprising:
a word line formed at a first end of the pillar and extending along a first direction, the word line coupled to the gate pattern; and
a second bit line formed at a second end of the pillar and extending along a second direction perpendicular to the first direction, the second bit line coupled to the first bit line.
